(19) United States
(12) Patent Application Publication
(10) Pub. No.: US 2025/0383538 A1
(43) Pub. Date: Dec. 18, 2025

(54) ENDOSCOPIC LENS MODULE, ARRAY-TYPE OPTICAL IMAGE SENSOR MODULE, OPTICAL IMAGE SENSOR MODULE, AND MANUFACTURING METHOD THEREOF

(71) Applicant: Medimaging Integrated Solution, Inc., Hsinchu (TW)

(72) Inventors: Shangyi WU, Hsinchu (TW); Hsin-Hsien HSIEH HSIEH, Hsinchu (TW); Jiunwei CHEN, HsinchuHsinchu (TW)

(21) Appl. No.: 19/093,842

(22) Filed: Mar. 28, 2025

(30) Foreign Application Priority Data
Jun. 12, 2024 (TW) 113121737

(51) Int. Cl. G02B 23/24; H04N 23/50; H04N 23/55; H10F 39/00; H10F 39/10

(52) U.S. Cl. CPC G02B 23/2484; G02B 23/2407; H10F 39/024; H10F 39/107; H10F 39/8057; H10F 39/8063; H04N 23/55; H04N 23/555

(57) ABSTRACT

A manufacturing method of an endoscopic lens module involves arranging multiple lens barrel channels and alignment marks on a positioning base, placing lenses into the channels, and using adhesive material to fix them to form the lens module. A flat glass layer is placed on the other side of the positioning base, and the positioning base is then cut according to the alignment marks to create glue flowing runners. Light-shielding material is injected into the glue flowing runners and cured to form the array-type optical image sensor module. Finally, the light-shielding material is cut along the sidewalls of the glue flowing runners to separate the base units and create multiple optical image sensor modules of endoscopic lens assemblies. Therefore, the present invention enables the efficient mass production of high-quality optical image sensor modules of endoscopic lens assemblies and allows flexible configuration of image sensors to achieve optimal imaging results.

### BACKGROUND OF THE INVENTION

### 1. Field of the Invention

The present invention relates to a technology of endoscopes, particularly to an endoscopic lens module, an array-type optical image sensor module, an optical image sensor module, and a manufacturing method thereof.

### 2. Description of the Prior Art

The current endoscopic lens assemblies have been trending toward miniaturization. In general, the image capturing lens module having been assembled to the barrel, which is called the barrel-type lens module thereinafter, is aligned and assembled to the image sensor that has been bonded to the carrier board (PCB or FPC) through an automatic alignment device. A multi-axis adjustment machine is used to perform adjusting the image sensor and obtain the optimized image. Then, an adhesive is dispensed to fix the relative position of the image capturing lens module and the image sensor and obtain a complete image sensor module having an image capturing lens module. However, the abovementioned technology is used to fabricate a single image sensor module. In the abovementioned technology, the assembled barrel-type lens module is further assembled to the image sensor. Thus, the output image sensor module has a larger outer dimension. After the LED light source is added, the final size of the distal end of the endoscope will be too large to meet the tendency of miniaturization.

Another technology of fabricating optical image sensor modules adopts a wafer-level technology: the completed wafer-level package sensors and the corresponding wafer-level lenses are aligned and stacked together adhesively layer by layer. The finished array is cut to obtain the required image sensor modules. Then, a black or dark-color material is coated on the peripheral of the image sensor module to shield light lest stray light enter the lens and affect the image quality. However, the wafer-level package process is unlikely to automatically align the lenses and the image sensors. Each wafer-level lens can only be aligned and adhesively assembled through alignment points. In other words, the wafer-level package process cannot adjust the position according to image quality and is unlikely to control the imaging quality of each image sensor on the wafer. Thus, the yield thereof is degraded. Besides, the wafer-level package process is unlikely screen out the damaged image sensors during fabrication. Though some damaged image sensors have been known, the lens package process cannot be interrupted but must be completed thoroughly. Then is increased the cost and degraded the yield. Besides, the optics specifications (such as the field of view and the depth of field) of the abovementioned technology are unlikely to adjust as long as the specifications are decided. Therefore, they cannot be adjusted to satisfy requirements of different endoscopes by the user during usage. If the specifications are intended to be changed, much money would be spent in redesigning the forming molds of the wafer-level lens. Hence, the wafer-level lens is more expensive than the barrel-type lens in such a situation. Therefore, the wafer-level lens is hard to fabricate, lower in yield rate, and higher in cost.

Accordingly, the present invention proposes an endoscopic lens module, an array-type optical image sensor module, an optical image sensor module, and a manufacturing method thereof to overcome the problems of the conventional technologies.

### SUMMARY OF THE INVENTION

One objective of the present invention is to provide a lens module, an array-type optical image sensor module, an optical image sensor module, and a manufacturing method thereof to solve the conventional problems of endoscopes, including too large a lens assembly, complicated fabrication process, high cost, and inflexibility of adjusting optics specifications.

In order to achieve the abovementioned objective, the present invention provides a manufacturing method of an endoscopic lens module, which comprises steps:
providing a positioning base, wherein the positioning base has a first face, a second face opposite to the first face in the vertical direction, and a plurality lens barrel channels; a plurality of alignment marks is formed on the positioning base; the plurality of lens barrel channels penetrates the first face and the second face and cooperates with the plurality of alignment marks to define a plurality of base units, which is arranged in array;
placing a plurality of lenses into the corresponding lens barrel channel layer by layer in each base unit;
filling a resin material into the gaps between the plurality of lenses to fix the plurality of lenses adhesively;
arranging a flat glass layer on the second face of the positioning base;
dicing the positioning base along the alignment marks to form a plurality of glue-flowing runners;
filling a light-shielding material into the plurality of glue flowing runners and curing the light-shielding material to wrap the sidewalls of the plurality of glue flowing runners, and preventing the light-shielding material from covering the surfaces of the plurality of lenses; and
cutting the light-shielding material along the sidewalls of the glue flowing runners to form optical-barrier layers on the outer sidewalls of the plurality of lens barrel channels and separate the plurality of base units to form lens modules.

In order to achieve the abovementioned objective, the present invention also provides a manufacturing method of an optical image sensor module, which comprises steps:
providing an endoscopic lens module, which is manufactured by the abovementioned manufacturing method of an endoscopic lens module;
after filling a resin material into the gaps between the plurality of lenses to fix the plurality of lenses adhesively, or before filling the light-shielding material into the plurality of glue flowing runners and curing the light-shielding material, or after filling the light-shielding material into the plurality of glue flowing runners and curing the light-shielding material, attaching an image sensor onto one surface of the plurality of lenses, wherein one side of the image sensor protrudes outward with respect to the lenses and neighbors the first face of the positioning base to form an array-type optical image sensor module; after cutting the light-shielding material along the sidewalls of the glue flowing runners, a plurality of optical image sensor modules is generated.

In order to achieve the abovementioned objective, the present invention also provides an optical image sensor module, which comprises one of the plurality of the optical image sensor modules manufactured by the abovementioned manufacturing method of an optical image sensor module.

In order to achieve the abovementioned objective, the present invention also provides an array-type optical image sensor module, which comprises a positioning base, a plurality of lens modules, a flat glass layer, an optical-blocking layer, and a plurality of image sensors. The positioning base includes a first face, a second face opposite to the first face in the vertical direction, a plurality lens barrel channels, and a plurality of alignment marks. The plurality of lens barrel channels penetrates the first face and the second face and cooperates with the plurality of alignment marks to define a plurality of base units, which is arranged in array. A plurality of glue flowing runners is formed on the positioning base along the alignment marks. Each lens module comprises a plurality of lenses. The plurality of lenses is disposed inside the plurality of lens barrel channels. A resin material is disposed between the gaps of the plurality of lenses. The flat glass layer is disposed on the second face of the positioning base. The optical-blocking layers are formed inside the plurality of glue flowing runners, wrapping the outer sidewalls of the post-cut lens barrel channels and prevented from covering the surfaces of the plurality of lens modules. One side of the image sensor is attached onto one surface of the lens module. The opposite side of the image sensor protrudes outward with respect to the lenses and neighbors the first face of the base unit.

In conclusion, the present invention provides a lens module, an array-type optical image sensor module, an optical image sensor module, and a manufacturing method thereof. The lens module, which is fabricated by the manufacturing method, including the light-shielding material but free of the image sensor, may form a lens module matching the size of the image sensor after the cutting processes. The lens module may be integrated with the image sensor to form an optical image sensor module able to capture images.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a flowchart of a first embodiment of a manufacturing method of a lens module of the present invention;

FIG. 2A is a diagram schematically showing Step S1 in FIG. 1;

FIG. 2B is a diagram schematically showing Step S2 in FIG. 1;

FIG. 2C, FIG. 2D, FIG. 2E and FIG. 2F are diagrams schematically showing Step S3 in FIG. 1;

FIG. 2G is a diagram schematically showing Step S4 in FIG. 1;

FIG. 2H is a diagram schematically showing Step S5 in FIG. 1;

FIG. 2I is a diagram schematically showing Step S6 in FIG. 1;

FIG. 2J is a diagram schematically showing Step S7 in FIG. 1;

FIG. 3A is a flowchart of a first embodiment of a manufacturing method of an optical image sensor module of the present invention;

FIG. 3B is a diagram schematically showing Step S17 in FIG. 3A;

FIG. 3C is a diagram schematically showing Step S18 in FIG. 3A;

FIG. 4 is a flowchart of a second embodiment of a manufacturing method of an optical image sensor module of the present invention;

FIG. 5A and FIG. 5B are diagrams schematically showing Steps S23-S25 in FIG. 4;

FIG. 5C is a diagram schematically showing Step S26 in FIG. 4;

FIG. 5D is a diagram schematically showing Step S27 in FIG. 4;

FIG. 5E is a diagram schematically showing Step S28 in FIG. 4;

FIG. 6 is a flowchart of a third embodiment of a manufacturing method of an optical image sensor module of the present invention;

FIG. 7A is a diagram schematically showing Step S36 in FIG. 6;

FIG. 7B is a diagram schematically showing Step S37 in FIG. 6;

FIG. 8 is a diagram schematically showing another embodiment of a positioning base of the present invention;

FIG. 9 is a diagram schematically showing yet another embodiment of a positioning base of the present invention;

FIG. 10 is a diagram schematically showing an embodiment of an array-type optical image sensor module of the present invention;

FIG. 11A and FIG. 11B are diagrams schematically showing an embodiment of an optical image sensor module of the present invention.

### DESCRIPTION OF THE PREFERRED EMBODIMENTS

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

The embodiments of the present invention will be further demonstrated in details hereinafter in cooperation with the corresponding drawings. In the drawings and the specification, the same numerals represent the same or the like elements as much as possible. For simplicity and convenient labelling, the shapes and thicknesses of the elements may be exaggerated in the drawings. It is easily understood: the elements belonging to the conventional technologies and well known by the persons skilled in the art may be not particularly depicted in the drawings or described in the specification. Various modifications and variations made by the persons skilled in the art according to the contents of the present invention are to be included by the scope of the present invention.

It should be explained: the steps of the method of the present invention are not necessarily performed in the sequences described in the embodiments but may be undertaken in different sequences in practical operation.

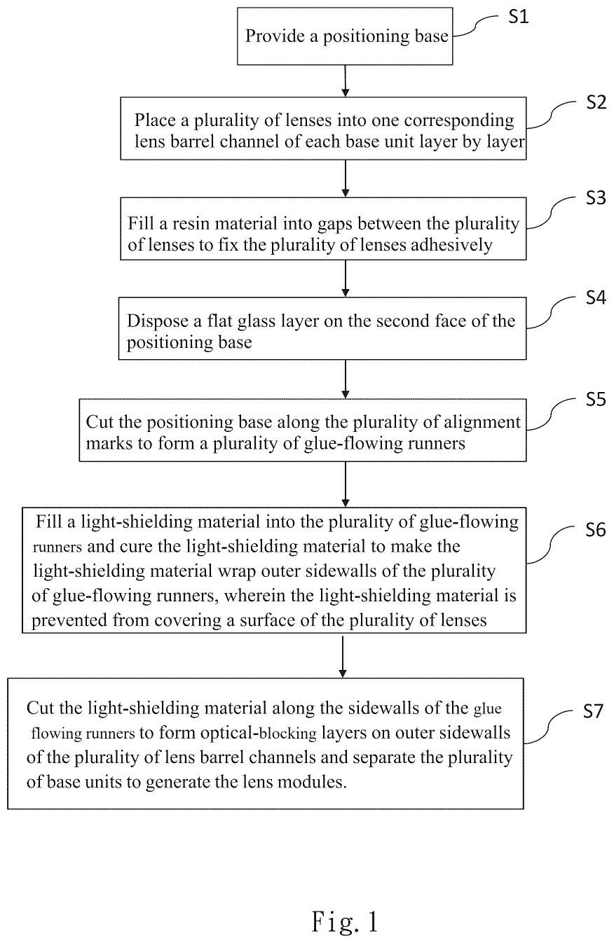

FIG. 1 shows a flowchart of a manufacturing method of an endoscopic lens module according to one embodiment of the present invention. The manufacturing method of an endoscopic lens module of the present invention comprises Steps S1-S7.

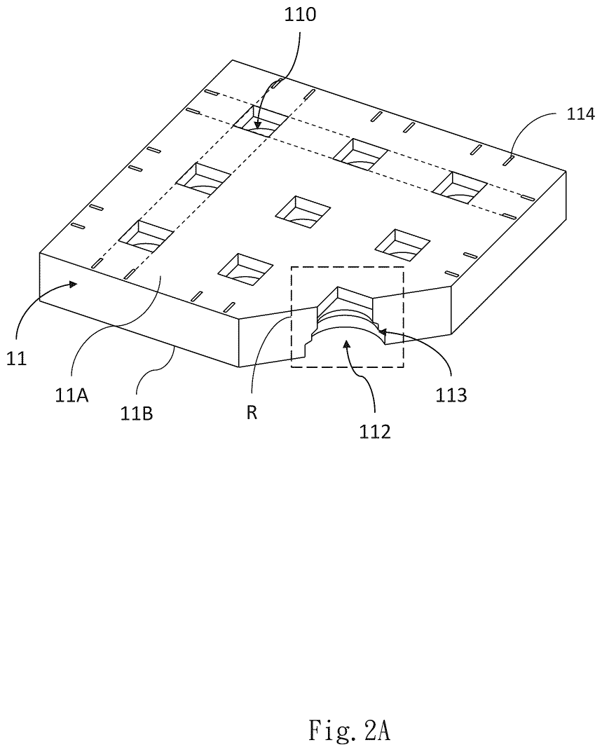

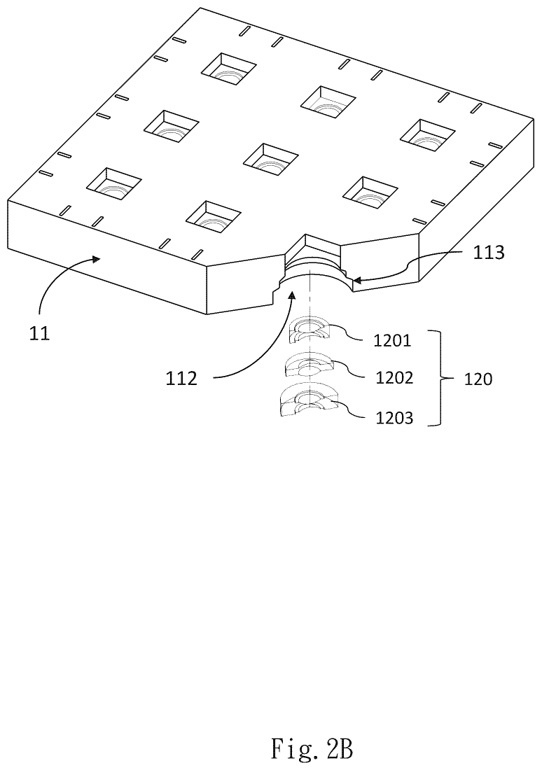

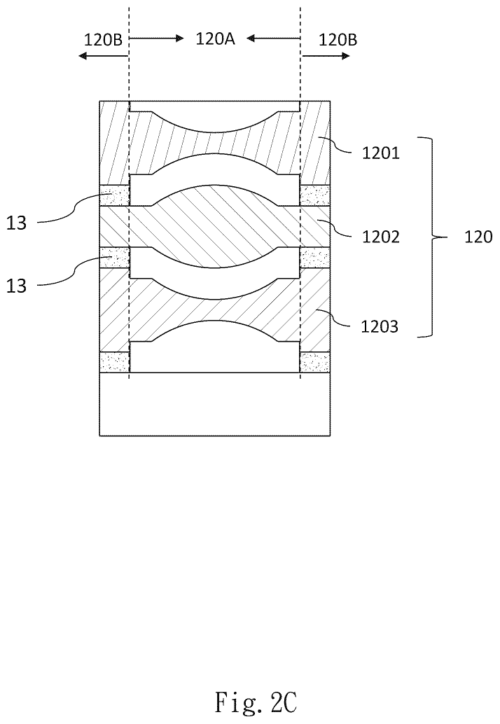

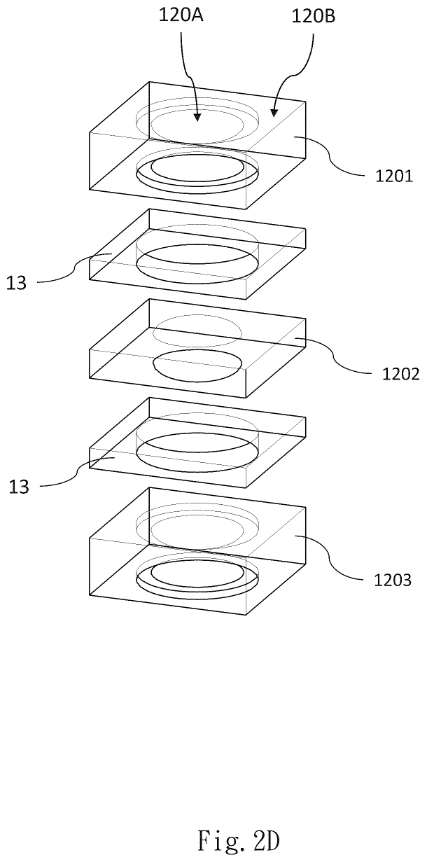

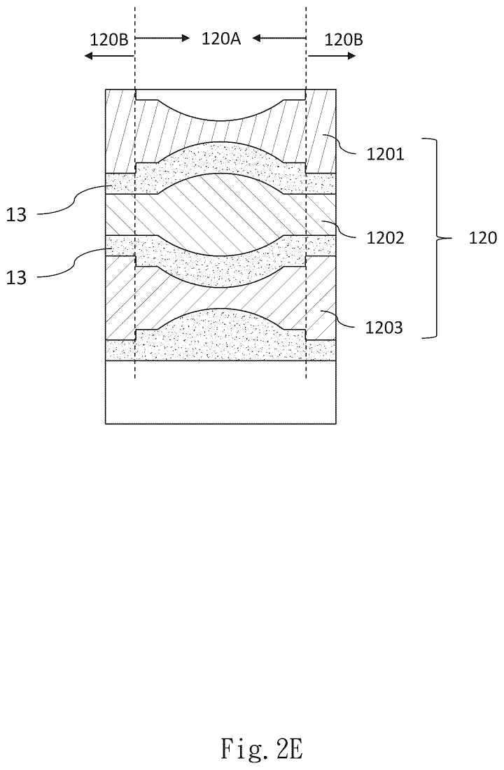

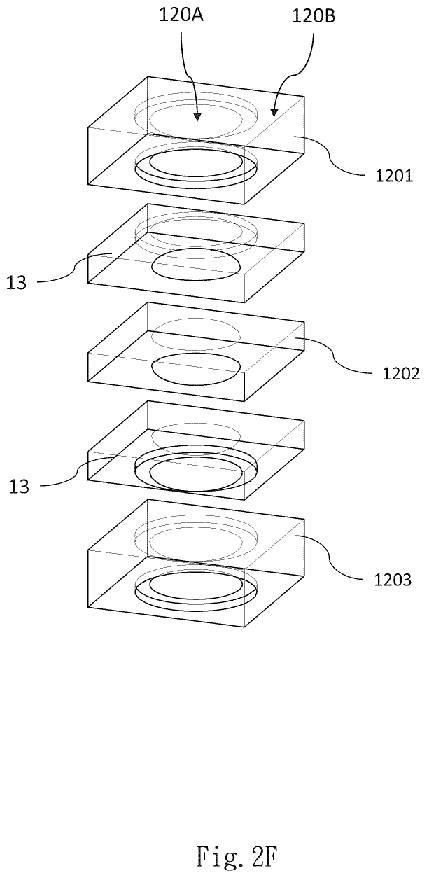

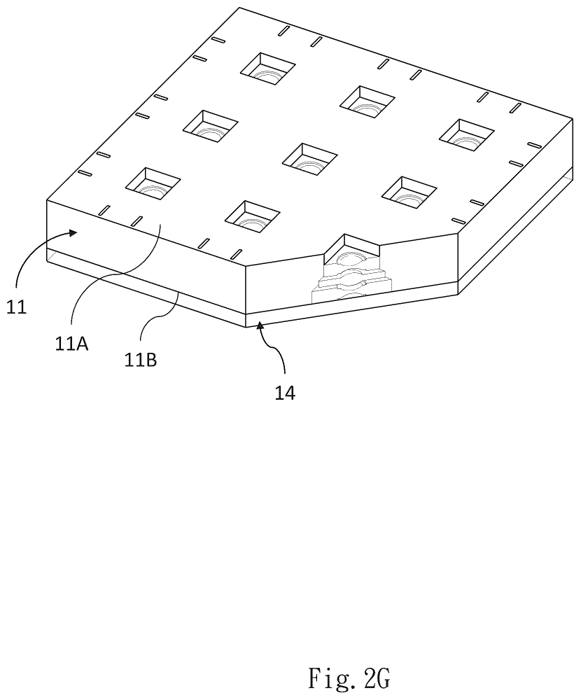

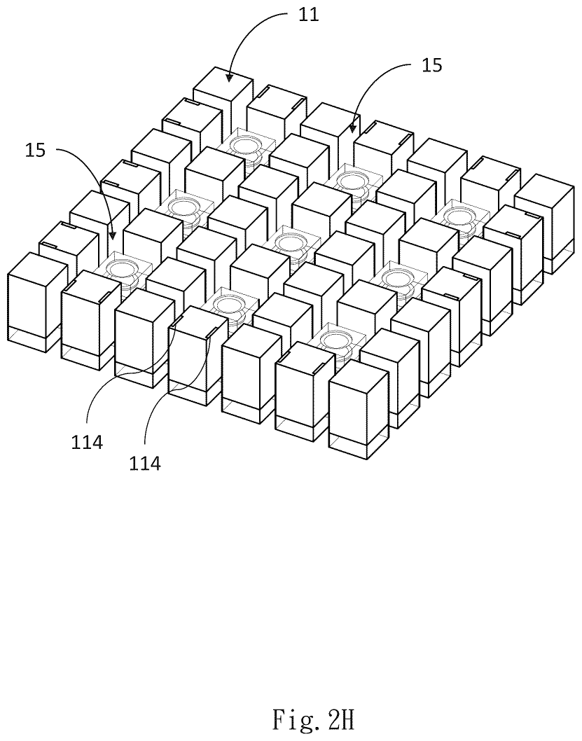

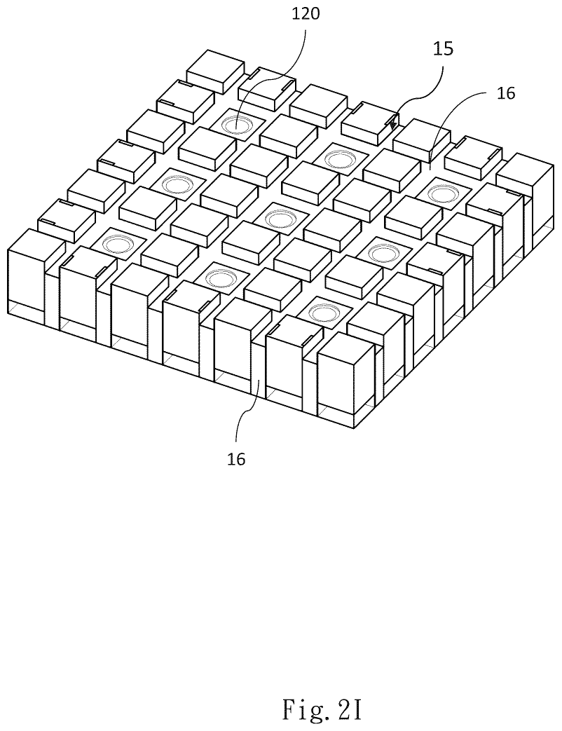

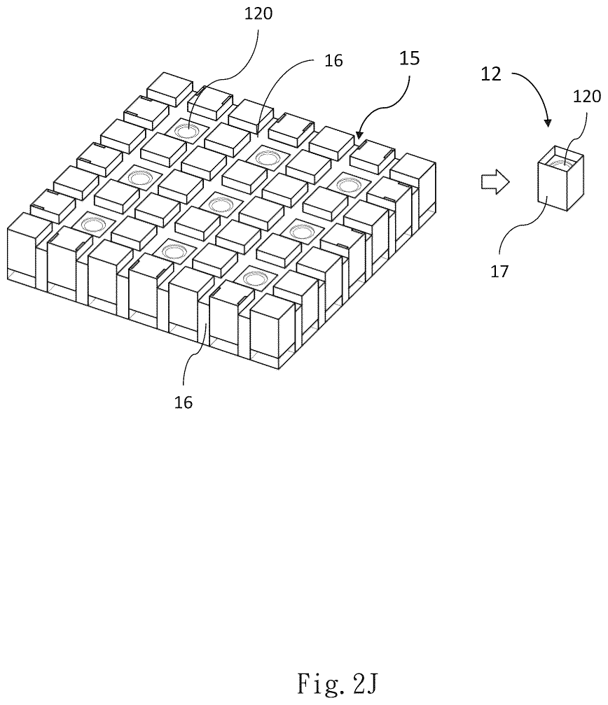

Refer to FIG. 1 and FIG. 2A. Step S1 includes providing a positioning base 11. The positioning base 11 has a first face 11A, a second face 11B, and a plurality of lens barrel channels 112, wherein the second face 11B is opposite to the first face 11A in the vertical direction. The positioning base 11 has a plurality of alignment marks 114. The plurality of lens barrel channels 112 each penetrates the first face 11A and the second face 11B and cooperates with the plurality of alignment marks 114 to define a plurality of base units 110, which are arranged in array. In FIG. 2A, the plurality of alignment marks 114 are respectively formed on the edges of the first face 11A. However, the present invention is not limited by the drawing. The alignment marks are connected by dotted lines, and the dotted lines intersect mutually to define the plurality of base units 110, which are distributed in array. In the local region R, the partial cross-sectional view of the lens barrel channel 112 is revealed, wherein a plurality of support structures 113 are formed on the inner sidewall of the lens barrel channel 112. The depths of the support structures 113 and the spacings between the support structures 113 may be designed according to the optical design and the lens sizes. In some embodiments, molds and an injection-molding technology may be used to produce the positioning base 11 having lens barrel channels 112 distributed in array. In some embodiments, the cross section of the lens barrel channel 112 may have a circular shape or a rectangular shape. In FIG. 2A, the cross section of the lens barrel channel 112 is exemplified by a circular shape. However, the present invention is not limited by the drawing.

Refer to FIG. 1 and FIG. 2B. Step S2 includes disposing a plurality of lenses 120 inside the lens barrel channel 112 of each base unit 110 layer by layer. The plurality of lenses 120 is respectively denoted by 1201, 1202 and 1203, whereby to identify different lenses 120. The lens 1201, the lens 1202, and lens the 1203 may be placed into the lens barrel channels 112 in sequence according to the widths thereof. The edges of the lens 1201, the lens 1202, and lens the 1203 respectively press against the support structures 113. The support structures 113 respectively have support faces, and the edges of the lens 1201, the lens 1202, and lens the 1203 respectively press against the support faces.

Refer to FIG. 1 and FIG. 2C-2F. Step S3 includes filling a resin material 13 into the gaps between the plurality of lenses 120 to fix them adhesively. In FIGS. 2C-2F, the lens 120 has an imaging area 120A and a non-imaging area 120B. The imaging area 120A is located at the central region of the lens 120; the non-imaging area 120B surrounds the imaging area 120A. The adhesively-joined regions may have different patterns. In FIG. 2C and FIG. 2D, the resin material 13 is filled into the non-imaging area 120B. In FIG. 2E and FIG. 2F, the resin material 13 is filled into the imaging area 120A and the non-imaging area 120B.

Refer to FIG. 1 and FIG. 2G. Step S4 includes disposing a flat glass layer 14 on the second face 11B of the positioning base 11. The flat glass layer 14 is to protect the lenses inside the lens barrel channel. Besides, the flat glass layer 14 has an anti-reflection coating film for enhancing the effect of optical design.

In some embodiments, another flat glass layer (not shown in the drawings) is disposed on the first face 11A of the positioning base 11. Alternatively, one of the lenses 120 is replaced by a flat glass layer, and the flat glass layer is placed into the lens barrel channel 112. In the following steps, the image sensor is joined with the flat glass layer. Thereby, positioning and installation of the image sensor is more secure. Although another glass layer is not depicted in the drawings, the persons having ordinary knowledge of the art should be able to understand the characteristics and structure thereof.

Step S4 may be followed by a step: disposing a support interposer under the positioning base 11. The support interposer may be a temporary one. The method of installing the support interposer is dependent on the material thereof. For example, if the support interposer is an adhesive tape, the support interposer may be stuck onto the bottom of the positioning base 11 with the adhesive agent. Thereby, the workpieces may be prevented from being separated or displaced during the following cutting step lest the manufacturing process be affected. The light-shielding material and the curing method thereof may be selected according to the material of the support plate for the succeeding curing step of the light-shielding material.

Refer to FIG. 1 and FIG. 2H. Step S5 includes dicing the positioning base 11 along the plurality of alignment marks 114 to form a plurality of glue flowing runners 15.

Refer to FIG. 1 and FIG. 2I. Step S6 includes filling a light-shielding material 16 into the plurality of glue flowing runners 15 and curing the light-shielding material 16. Thereby, the light-shielding material 16 wraps the outer sidewalls of the lens barrel channels, wherein the light-shielding material 16 is prevented from covering the surfaces of the lenses 120. If there is a step of installing a temporary support interposer after Step S4, the light-shielding material 16 or the curing method will be selected according to the material of the support interposer. The curing methods include a UV-curing method and a thermal-curing method.

Refer to FIG. 1 and FIG. 2J. Step S7 includes cutting the light-shielding material 16 along the sidewalls of the glue flowing runners 15 to form optical-blocking layers 17 around the outer sidewalls of the lens barrel channels 15 and separate the base units to form the lens modules 12.

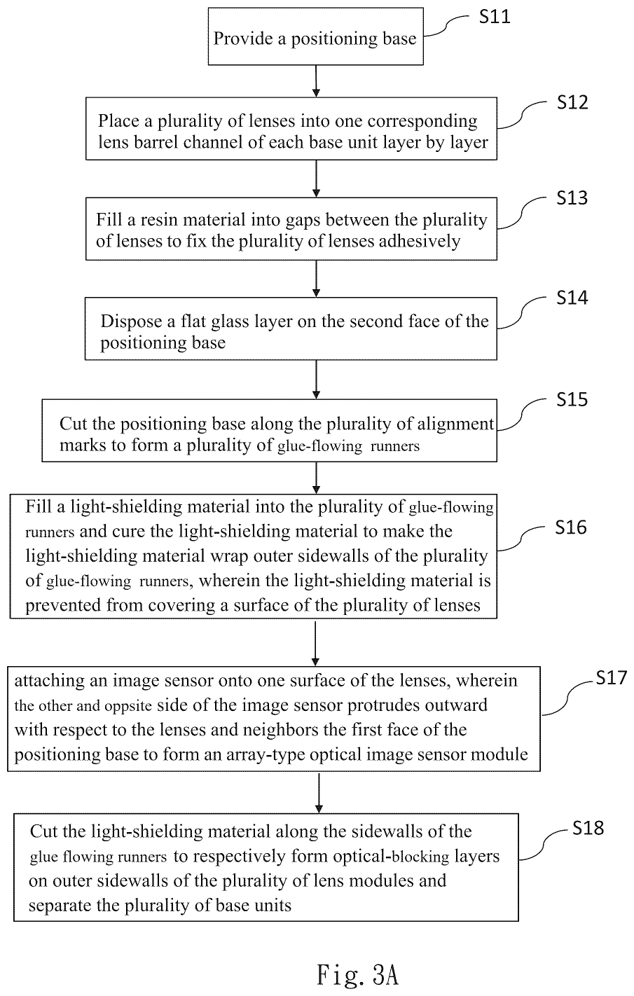

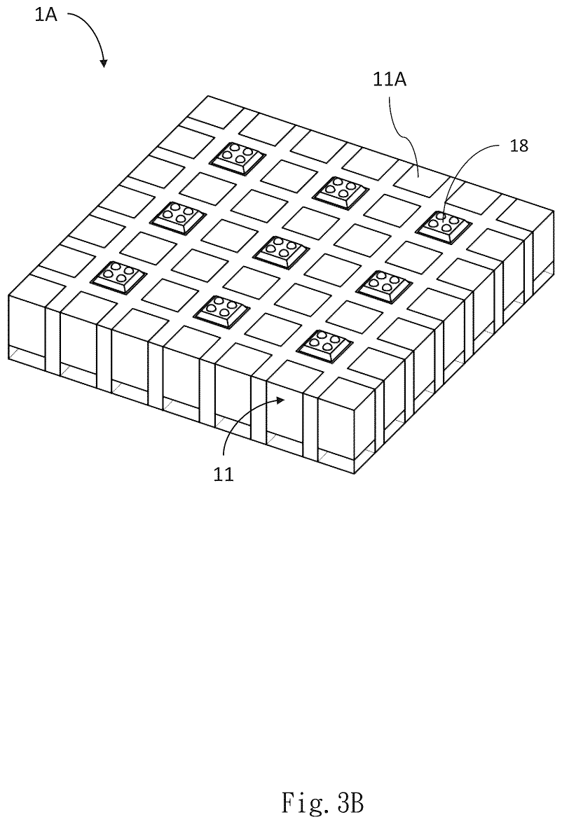

Refer to FIGS. 3A-3C for a first embodiment of a manufacturing method of an optical image sensor module of the present invention. The manufacturing method of an optical image sensor module comprises Steps S11-S18. Steps S11-S16 is the same as the aforementioned Steps S1-S6 and will not repeat herein. Refer to FIGS. 2A-2I again for Steps S11-S16. In this embodiment, Step S17 is undertaken after the step of the aforementioned manufacturing of a lens module: filling the light-shielding material 16 into the plurality of glue flowing runners 15 and curing the light-shielding material 16.

Refer to FIG. 3A and FIG. 3B. Step S17 includes attaching one side of an image sensor 18 on one surface of the lens 120 to form an array-type endoscopic optical image sensor module 1A, wherein another side of the image sensor 18 protrudes outward with respect to the lens 120 and neighbors the first face 11A of the positioning base 11.

It should be noted: a wafer-level optical measurement step may be added to the process according to requirement. For example, a wafer-level optical measurement may be undertaken after Step S17 to examine whether there is any defective product in the lens modules. If there is a defective product in the lens modules, the position of the defective product is labeled. If no defective product is found, the process proceeds to Step S18.

Refer to FIG. 3A and FIG. 3C. Step S18 includes cutting the light-shielding material along the glue flowing runners to form optical-blocking layers 17 around the lens modules 12 and separate the plurality of base units. Thus, a plurality of optical image sensor modules 20 is generated after cutting the array-type optical image sensor module 1A. Therefore, the manufacturing method of the present invention can mass produce the optical image sensor modules 20. In Step S18, a preset thickness of the light-shielding material on the sidewalls of the glue flowing runners is reserved to function as the optical-blocking layer 17 of the lenses lest stray light enter the lens module 12 and affect the image quality.

In order to facilitate fabrication and assemblage, the first face 11A of the positioning base 11 is faced upward, and the second face 11B is faced downward. In practical application after production, the optical image sensor module 20 is flipped over to make the image sensor 18 on the bottom of the whole optical image sensor module 20. Then, the image sensor is electrically connected with other elements. As shown in the right portion of FIG. 3C, after the array-type optical image sensor module 1A has been cut, the optical image sensor module 20 is turned 180 degrees. However, the present invention is not limited by the example. In practical application, the optical image sensor module 20 may be turned according to requirement.

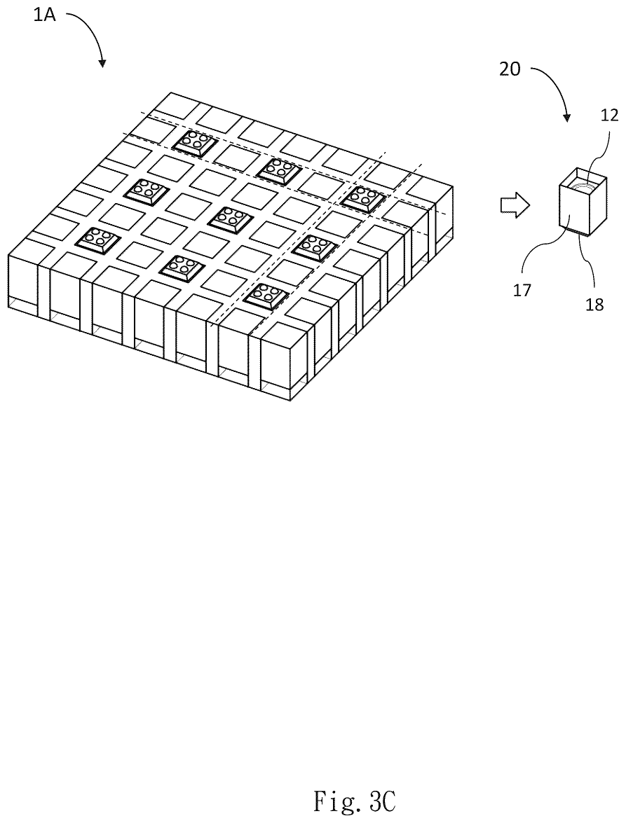

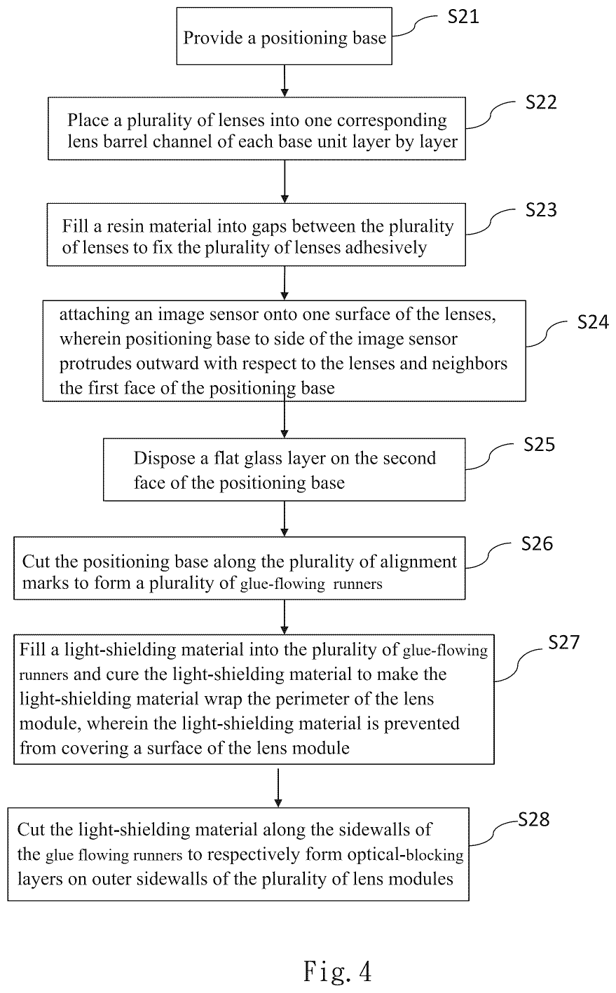

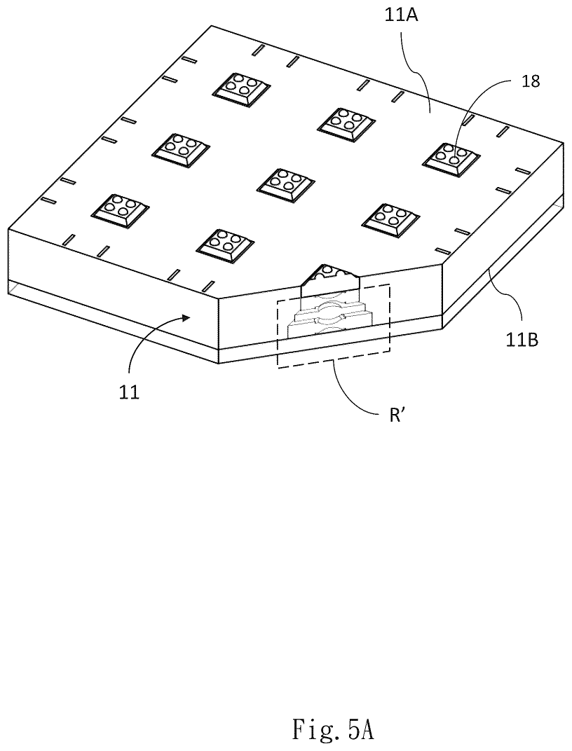

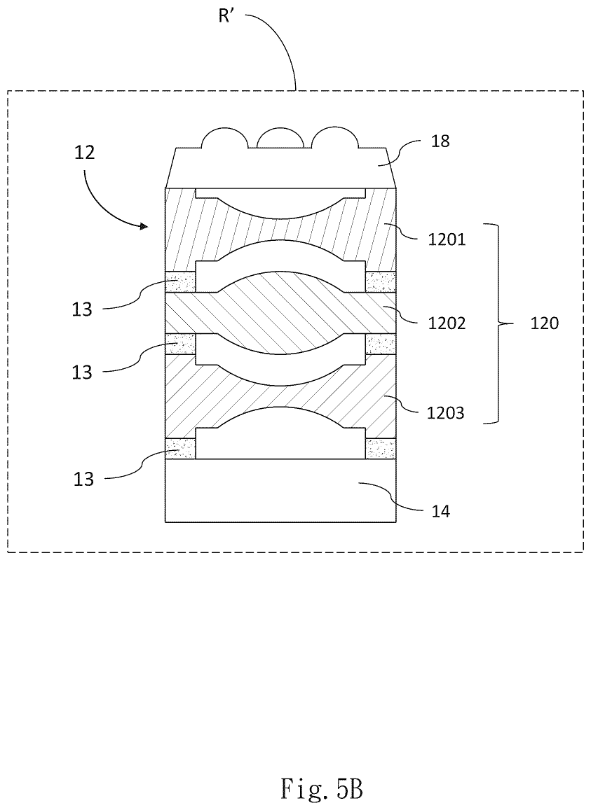

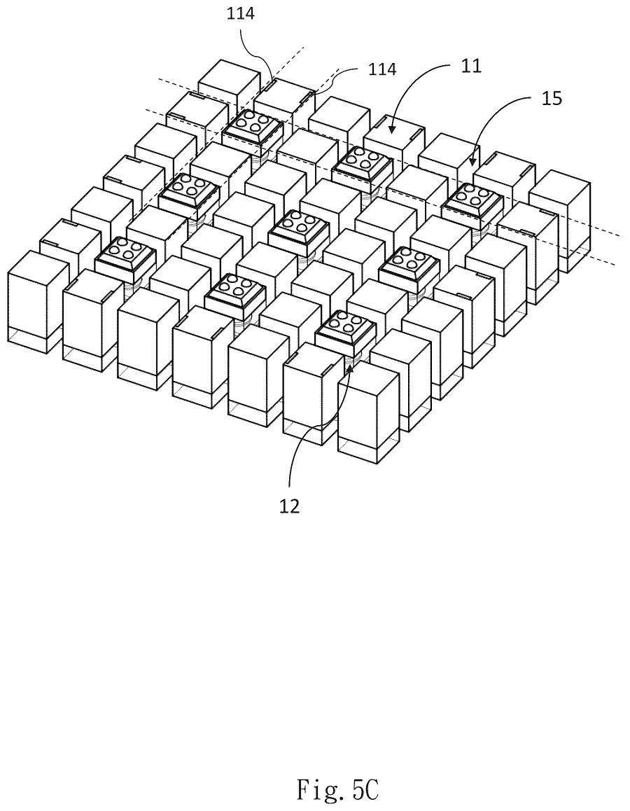

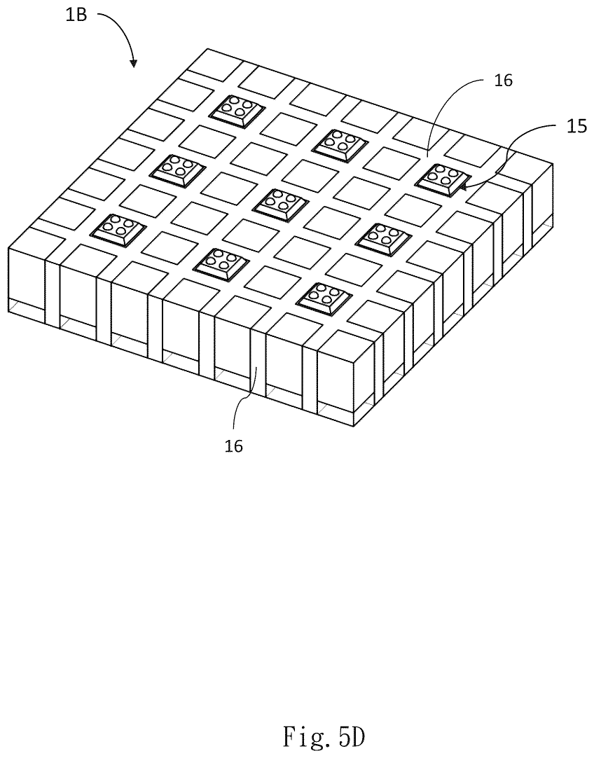

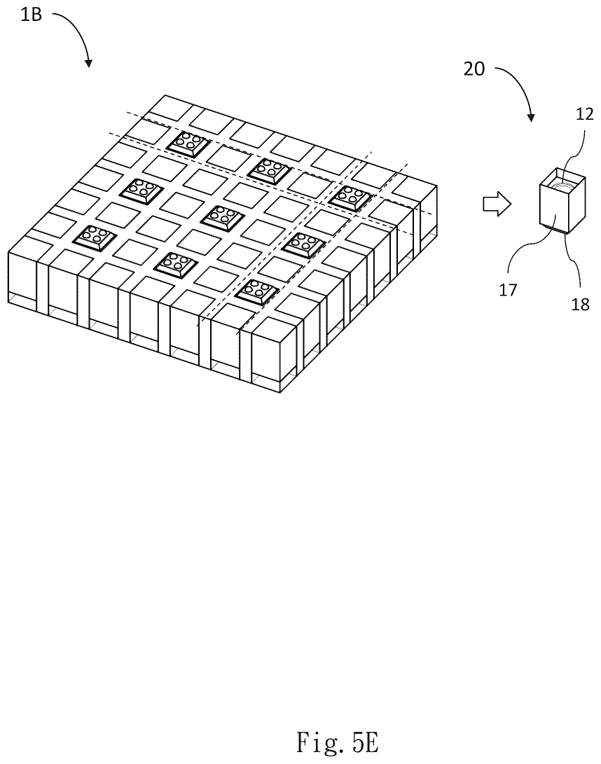

Refer to FIG. 4 and FIGS. 5A-5E for a second embodiment of a manufacturing method of an optical image sensor module of the present invention. The manufacturing method of an optical image sensor module comprises Steps S21-S28.

Step S21 includes providing a positioning base. Step S22 includes placing a plurality of lenses into the plurality of lens barrel channels layer by layer. Step S23 includes filling a resin material into the gaps between the plurality of lenses and curing the resin material. Step S21 has been illustrated in FIG. 2A. Step S22 has been illustrated in FIG. 2B. Step S23 has been illustrated in FIGS. 2C-2F. Therefore, Steps S21-S23 will not repeat herein.

Refer to FIG. 4, FIG. 5A and FIG. 5B, Step S24 includes attaching one side of an image sensor 18 onto one surface of the lenses, wherein another side of the image sensor 18 protrudes outward with respect to the lenses and neighbors the first face 11A of the positioning base 11. Step S25 includes disposing a flat glass layer 14 on the second face 11B of the positioning base 11, wherein it is shown in the local region R′: the lenses 120 (the lenses 1201, 1202 and 1203), the image sensor 18 and the flat glass layer 14 may be adhesively fixed by the resin material 13.

It should be noted: a wafer-level optical measurement step may be added to the process according to requirement. For example, a wafer-level optical measurement may be undertaken after Step S25 or after Step S27, including a step of examining whether there is any defective product in the lens modules after Step S25. If there is a defective product, the position of the defective product is labeled. If no defective product is found, the process proceeds to Step S26. Therefore, if the optical measurement is performed before Step S26, the defective products are abandoned, and the succeeding steps of the defective products would not be performed. Thus, the present invention can enhance fabrication efficiency and reduce waste. Alternatively, the optical measurement is overlooked after Step S25 but is undertaken after Step S27.

Refer to FIG. 4 and FIG. 5C. Step S26 includes cutting the positioning base 11 along the plurality of alignment marks 114 to form a plurality of glue flowing runners 15.

Refer to FIG. 4 and FIG. 5D. Step S27 includes filling a light-shielding material 16 into the plurality of glue flowing runners 15 and curing the light-shielding material 16 to make the light-shielding material 16 wrap the perimeters of the lens modules 12 to form an array-type optical image sensor module 1B, wherein the light-shielding material 16 is prevented from covering the surfaces of the lens modules 12.

Refer to FIG. 4 and FIG. 5E. Step S28 includes cutting the array-type optical image sensor module 1B to form a plurality of optical image sensor modules 20, wherein the light-shielding material is cut along the sidewalls of the glue flowing runners to form optical-blocking layers around the lens modules and separate the base units.

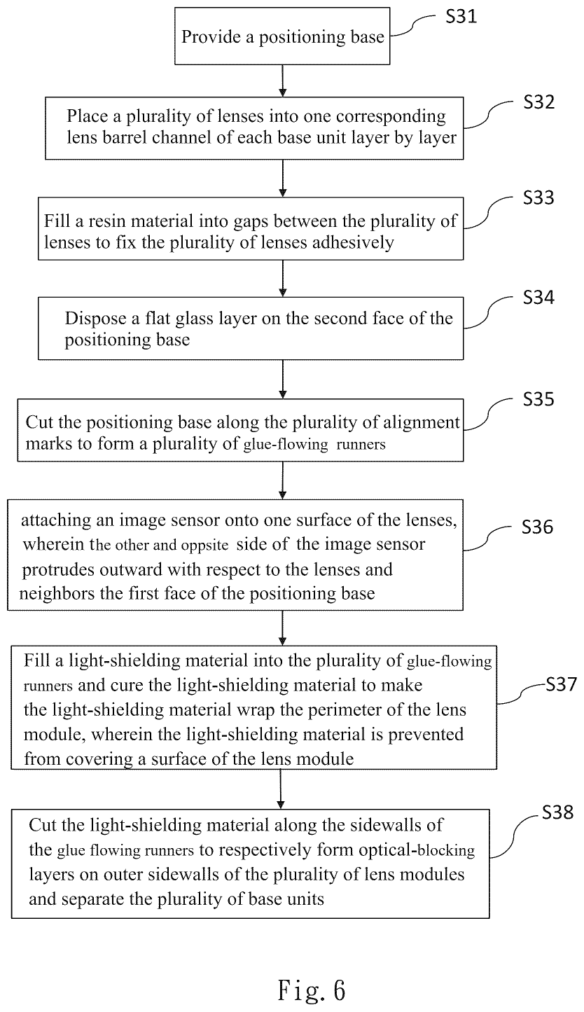

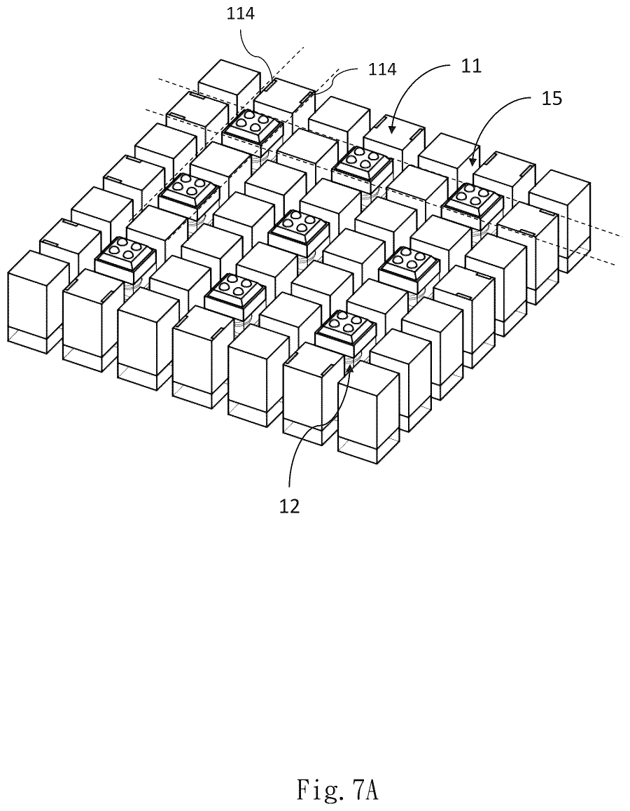

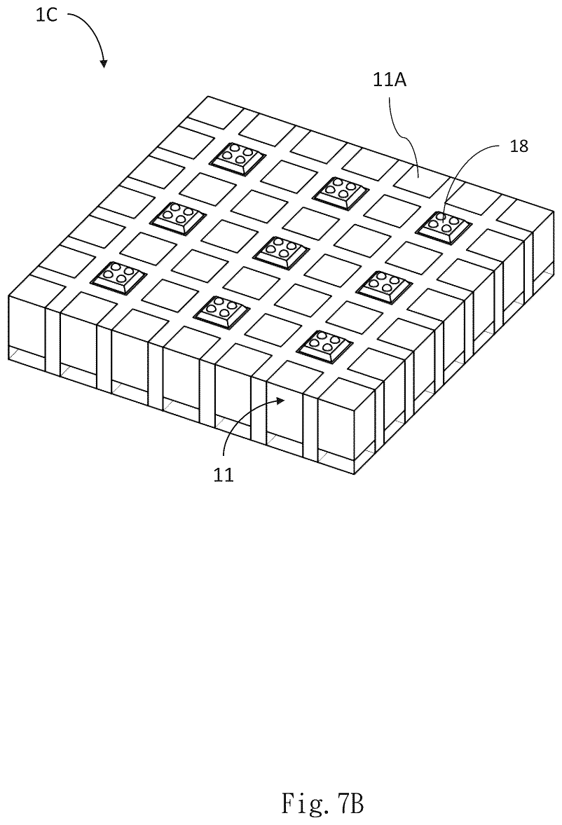

Refer to FIG. 6, FIG. 7A and FIG. 7B for a third embodiment of a manufacturing method of an optical image sensor module of the present invention. The manufacturing method of an optical image sensor module comprises Steps S31-S38. The third embodiment is different from the first embodiment in Step S36 and Step S37. Steps S31-S35 are the same as Steps S11-S15. Step S38 is the same as Step S18. Therefore, neither Steps S31-S35 nor Step S18 will repeat herein.

Refer to FIG. 6 and FIG. 7A. Step S36 includes attaching one side of the image sensor 18 on one surface of the lens, wherein another side of the image sensor 18 protrudes outward with respect to the lens and neighbors the first face 11A of the positioning base 11.

Refer to FIG. 6 and FIG. 7B. Step S37 includes filling a light-shielding material 16 into the plurality of glue flowing runners 15 and curing the light-shielding material 16 to make the light-shielding material 16 wrap the perimeters of the lens modules 12 to form an array-type optical image sensor module 1C, wherein the light-shielding material 16 is prevented from covering the surfaces of the lens modules 12.

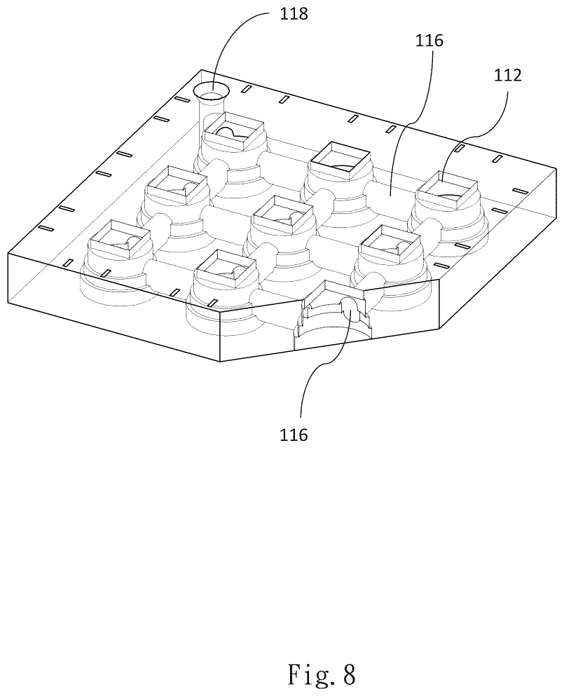

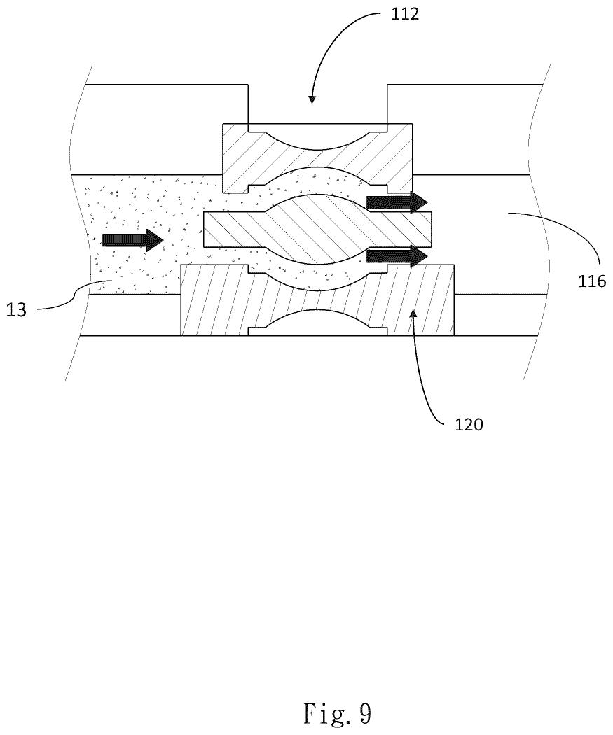

Refer to FIG. 8 and FIG. 9 for another embodiment of the positioning base. The positioning base may further comprise a plurality of runners 116 and a filling gate 118. One end of the filling gate 118 is located on the surface of the positioning base. In FIG. 8, one end of the filling gate 118 is arranged on the first face 11A. However, the present invention is not limited by the drawing. Another end of the filling gate 118 interconnects with the plurality of runners 116, and the plurality of runners 116 further interconnects with the plurality of lens barrel channels 112. In the aforementioned step of filling the resin material 13 into the gaps between the plurality of lenses 120 and curing the resin material 13, the resin material may be filled into the plurality of runners 116 through the filling gate 118; then the resin material flows into the plurality of lens barrel channels 112 and finally into the gaps between the lenses 120.

The structures of the array-type optical image sensor module and the optical image sensor module, which are fabricated by the manufacturing method of an optical image sensor module of the present invention, have been also introduced in the description of the method. However, the structures of the array-type optical image sensor module and the optical image sensor module will be further demonstrated in details below with the schematic illustrations to make the readers understand them more clearly.

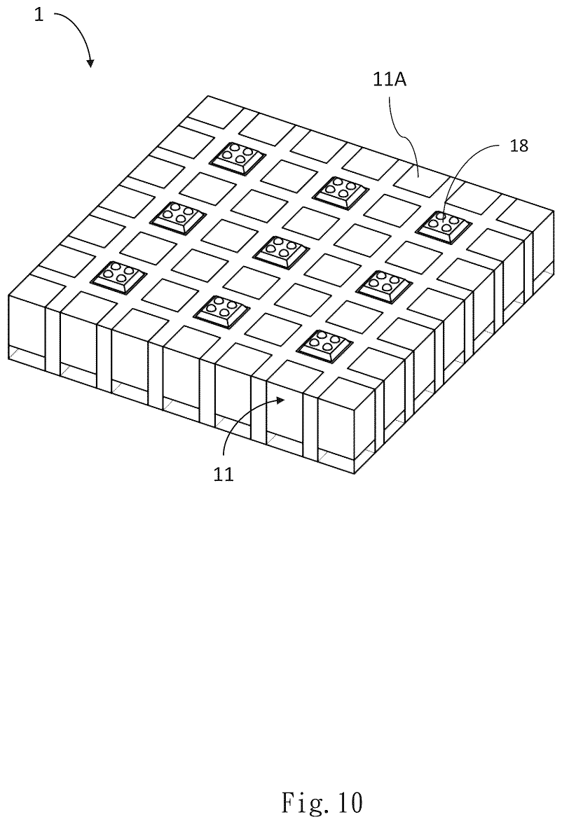

Refer to FIG. 10. The array-type optical image sensor module 1 may be fabricated by various embodiments of the aforementioned manufacturing method of an optical image sensor module. Refer to FIGS. 2A-2J, FIG. 3B and FIG. 3C to understand the details of the array-type optical image sensor module 1, which comprises a plurality of lens modules 12 and a plurality of image sensors 18. The plurality of lens modules 12 includes a positioning base 11, a plurality of lenses 120, a flat glass layer 14, and an optical-barrier layer 17.

The positioning base 11 includes a first face 11A, a second face 11B, and a plurality of lens barrel channels 112, wherein the second face 11B is opposite to the first face 11A in the vertical direction. The positioning base 11 also has a plurality of alignment marks 114. In the drawings, the plurality of alignment marks 114 is arranged on the edges of the first face 11A. However, the present invention is not limited by the drawings. The plurality of lens barrel channels 112 penetrates the first face 11A and the second face 11B and cooperates with the alignment marks 114 to define a plurality of base units 110, which are distributed in array. The positioning base 11 is cut along the alignment marks 114 to form the glue flowing runners 15. The plurality of lenses 120 is respectively disposed inside the base units 110, wherein The plurality of lenses 120 are placed inside the corresponding lens barrel channel 112 layer by layer. A resin material 13 is filled into the gaps between the plurality of lenses 120 and cured to join the lenses 120 adhesively. Optical-barrier layers 17 are disposed inside the glue flowing runners 15. The optical-blocking layers 17 are formed via filling a light-shielding material 16 into the glue flowing runners 15 and curing the light-shielding material 16. The optical-blocking layers 17 wrap the outer sidewalls 112 of the lens module 12 and is prevented from covering the surface of the lens module 12. The image sensor 18 is attached onto one surface of the lens module 12; another side of the image sensor 18 protrudes outward with respect to the lens module 12 and neighbors the first face 11A of the base unit 110.

The plurality of runners 116 and the filling gate 118 of the positioning base are not depicted in FIG. 10. However, it is learned from FIG. 8 and FIG. 9: one end of the filling gate 118 is disposed on the first face 11A, and another end of the filling gate 118 interconnects with one of the plurality of runners 116; the plurality of runners 116 interconnects with the plurality of lens barrel channels 112; the resin material is filled into the plurality of runners 116 through the filling gate 118; then the resin material flows into the plurality of lens barrel channels 112. The shape and size of the runners 116 and the connection method of the runners 116, the filling gate 118 and the lens barrel channels 112 may be designed according to requirement. The position, size and number of the filling gates 118 may be modified according to practical operation of resin filling, the bonding quality, and other requirements. The present invention is not limited by the drawings and embodiments.

It is preferred: the image sensor 18 is a CSP (Chip Scale Package) image sensor. The image sensor chip is packaged on the package substrate having the same size as the image sensor chip, whereby to reduce the size and weight of the package as much as possible. The image sensor 18 may be but is not limited to be an RGB image sensor, an infrared image sensor, a monochromatic image sensor, or a specialty image sensor.

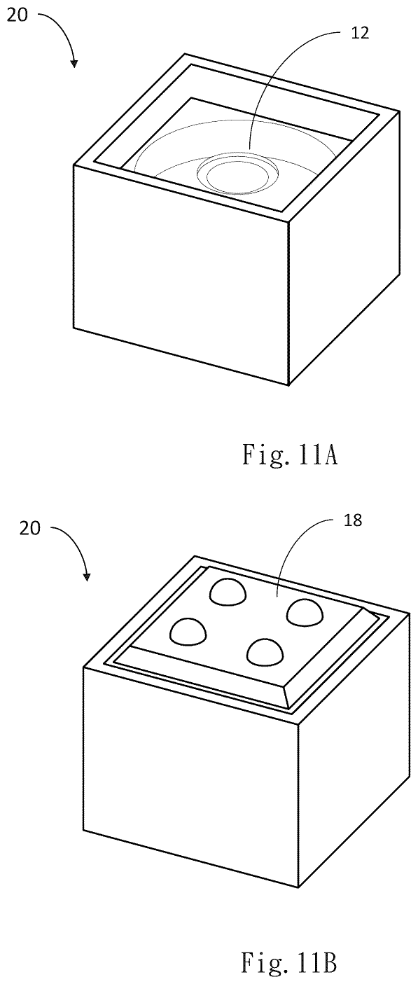

Refer to FIG. 11A and FIG. 11B, wherein FIG. 11A is the image of an optical image sensor module 20 and FIG. 11B is the image of the optical image sensor module 20 flipped over 180 degrees. The optical image sensor module 20 is obtained via cutting the aforementioned array-type optical image sensor module 1. The optical image sensor module 20 comprises a lens unit 12 and an image sensor 18.

Refer to FIGS. 2A-2I, FIG. 3B and FIG. 3C. The lens module 12 includes a base unit 110, a plurality of lenses 120, a flat glass layer 14 and an optical-barrier layer 17. The base unit 110 has a first face 11A, a second face 11B, and a lens barrel channel 112, wherein the second face 11B is opposite to the first face 11A in the vertical direction. The lens barrel channel 112 penetrates the first face 11A and the second face 11B. The lenses 120 are placed inside the lens barrel channel 112 layer by layer, and the lenses 120 are joined adhesively by a resin material 13. The flat glass layer 14 is disposed on the second face 11B of the base unit 110. The optical-blocking layer 17 wraps the outer sidewall 112 of the lens barrel channel 112 and is prevented from covering the surface of the lens module 12. One side of the image sensor 18 is disposed onto one surface of the lens module 12; another side of the image sensor 18 protrudes outward with respect to the lenses 120 and neighbors the first face 11A of the base unit 110.

A plurality of support structures 113 is formed on the inner sidewall of the lens barrel channel 112. The edges of the plurality of lenses 120 respectively press against the plurality of support structures 113. According to the widths of the lenses 120, the lenses 120 are placed inside the lens barrel channel 112 from small to large along the direction from the face 11A to the face 11B.

The efficacies of the endoscopic lens module, the array-type optical image sensor module, the optical image sensor module, and the manufacturing method thereof are stated as follows. Firstly, the cost of using the array-type lens barrels for assemblage is lower than the cost of using the wafer-level lenses, and the fabrication efficiency is also raised. Secondly, the lens assembly obtained using a single lens barrel to perform alignment and assemblage is superior to the lens assembly obtained via stacking the wafer-level lenses in precision and resolution and thus suitable for high pixel image sensors. Besides, the assembled lens modules may be examined with a wafer-level optical test to filter out defective products in advance, whereby to lower cost and promote yield. Further, the image sensors are stuck onto the lens barrel array where the lenses have been assembled, whereby to realize the wafer-level production mode, wherefore is achieved mass production and increased fabrication efficiency. Furthermore, the optical-barrier layers are also formed in fabrication. Thus, an image sensor module able to output high-quality images is generated.

The embodiments described above are only to exemplify the present invention but not to limit the scope of the present invention. The embodiments involving equivalent replacement or variation made easily according to the technical contents disclosed by the specification or claims are to be also included by the scope of the present invention.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the appended claims.

1. A manufacturing method of an endoscopic lens module, comprising steps:
providing a positioning base including a first face, a second face, and a plurality of lens barrel channels, wherein the first face is opposite to the second face in a vertical direction; the positioning base has a plurality of alignment marks; the plurality of lens barrel channels penetrates the first face and the second face and cooperates with the plurality of alignment marks to define a plurality of base units, which are distributed in array;
placing a plurality of lenses into one corresponding lens barrel channel of each base unit layer by layer;
filling a resin material into gaps between the plurality of lenses to fix the plurality of lenses adhesively;
disposing a flat glass layer on the second face of the positioning base;
dicing the positioning base along the plurality of alignment marks to form a plurality of glue flowing runners;
filling a light-shielding material into the plurality of glue flowing runners and curing the light-shielding material to make the light-shielding material wrap sidewalls of the plurality of glue flowing runners, wherein the light-shielding material is prevented from covering a surface of the plurality of lenses; and
cutting the light-shielding material along the sidewalls of the glue flowing runners to form optical-blocking layers on outer sidewalls of the plurality of lens barrel channels and separate the plurality of base units to generate lens modules.

2. The manufacturing method of an endoscopic lens module according to claim 1, further comprising a step:
after the step of disposing the flat glass layer on the second face of the positioning base,
undertaking a wafer-level optical measurement to examine whether there is any defective product in the lens modules; if there is a defective product in the lens modules, labeling a position of the defective product; if no defective product is found, undertaking the step of cutting the positioning base along the plurality of alignment marks to form the plurality of glue flowing runners.

3. The manufacturing method of an endoscopic lens module according to claim 1, wherein
after the step of filling the light-shielding material into the plurality of glue flowing runners and curing the light-shielding material to make the light-shielding wrap sidewalls of the plurality of glue flowing runners with the light-shielding material prevented from covering a surface of the plurality of lenses,
undertaking a wafer-level optical measurement to examine whether there is any defective product in the lens modules; if there is a defective product in the lens modules, labeling a position of the defective product; if no defective product is found, undertaking the step of cutting the light-shielding material along the sidewalls of the glue flowing runners to form optical-barrier layers on the sidewalls of the plurality of lens barrel channels.

4. The manufacturing method of an endoscopic lens module according to claim 1, wherein
the plurality of lenses respectively has imaging areas and a non-imaging area; the imaging area is located on a central region of the lens; the non-imaging area surrounds the imaging area;
in the step of filling the resin material into the gaps between the plurality of lenses to fix the plurality of lenses adhesively, the resin material is filled into the non-imaging area or filled into the non-imaging area and the imaging areas.

5. The manufacturing method of an endoscopic lens module according to claim 1, wherein
the positioning base includes a plurality of runners and a filling gate; one end of the filling gate is disposed on the first face; another end of the filling gate interconnects with one of the plurality of runners; the plurality of runners respectively interconnects with corresponding ones of the plurality of lens barrel channels;
in the step of filling the resin material into the gaps between the plurality of lenses to fix the plurality of lenses adhesively, the resin material is filled into the plurality of runner through the filling gate and then flows into the plurality of lens barrel channels.

6. The manufacturing method of an endoscopic lens module according to claim 1, wherein
a plurality of support structures is respectively formed on inner sidewalls of the plurality of lens barrel channels;
in the step of placing the plurality of lenses into one corresponding lens barrel channel of each base unit layer by layer, the plurality of lenses respectively presses against the plurality of support structures.

7. The manufacturing method of an endoscopic lens module according to claim 6, wherein according to the widths of the lenses, the lenses are placed inside the lens barrel channel from small to large; edges of the plurality of lenses respectively press against the plurality of support structures.

8. The manufacturing method of an endoscopic lens module according to claim 1, wherein
after the step of disposing the flat glass layer on the second face of the positioning base, two steps are undertaken:
disposing a support interposer on a bottom of the positioning base; and
selecting the light-shielding material or a curing method of the light-shielding material according to the support interposer.

9. A manufacturing method of an optical image sensor module, comprising steps:
providing a lens module, which is fabricated by the manufacturing method of an endoscopic lens module according to claim 1;
respectively attaching an image sensor onto each of the plurality of lenses after the step of filling the resin material into gaps between the plurality of lenses and joining the lenses adhesively, or before/after the step of filling the light-shielding material into the glue flowing runners and curing the light-shielding material, wherein another side of the image sensor protrudes outward with respect to lens and neighbors the first face to form an array-type optical image sensor module, and cutting the light-shielding material along the glue flowing runners to form a plurality of optical image sensor modules.

10. The manufacturing method of an optical image sensor module according to claim 9, further comprising a step:
undertaking a wafer-level optical measurement to examine whether there is any defective product in the lens modules; if there is a defective product in the lens modules, labeling a position of the defective product; if no defective product is found, undertaking the step of cutting the light-shielding material along the sidewalls of the glue flowing runners.

11. An optical image sensor module, which is one of the plurality of optical image sensor modules fabricated by the manufacturing method of an optical image sensor module according to claim 9.

12. An array-type optical image sensor module, comprising
a plurality of lens modules, including
a positioning base, including a first face, a second face, and a plurality of lens barrel channels, wherein the first face is opposite to the second face in a vertical direction; the positioning base has a plurality of alignment marks; the plurality of lens barrel channels penetrates the first face and the second face and cooperates with the plurality of alignment marks to define a plurality of base units, which are distributed in array; the positioning base has a plurality of glue flowing runners along the plurality of alignment marks;
a plurality of lenses, disposed in each base unit, and placed inside the lens barrel channel of the base unit layer by layer, wherein a resin material is filled into gaps between the plurality of lenses;
a flat glass layer, disposed on the second face of the positioning base;
an optical-blocking layer, disposed inside the plurality of glue flowing runners to wrap outer sidewalls of the plurality of lens barrel channels, and prevented from covering surfaces of the plurality of lenses; and
a plurality of image sensors, wherein one side of the image sensor is attached onto one surface of the lens module; another side of the image sensor protrudes outward with respect to the lenses and neighbors the first face of the positioning base.

13. The array-type optical image sensor module according to claim 12, wherein the plurality of lens modules respectively has imaging areas and a non-imaging area; the imaging area is disposed at a central position of the lens; the non-imaging area surrounds the imaging area; the resin material is disposed on the non-imaging area or disposed on the non-imaging area and the imaging areas.

14. The array-type optical image sensor module according to claim 12, wherein the positioning base has a plurality of runners and a filling gate; one end of the filling gate is disposed on a surface of the positioning base; another end of the filling gate interconnects with the plurality of runners; the resin material is filled into the plurality of runners through the filling gate and then flows into the plurality of lens barrel channels.

15. The array-type optical image sensor module according to claim 12, wherein an inner sidewall of each of the plurality of lens barrel channels has a plurality of support structures; the edges of the plurality of lenses respectively press against the plurality of support structures.

16. The array-type optical image sensor module according to claim 15, wherein according to widths of the lenses, the lenses are placed inside the lens barrel channel from small to large along the direction from the first face to the second face.
